(19) United States
(12) Patent Application Publication
(10) Pub. No.: US 2011/0102025 A1
(43) Pub. Date: May 5, 2011

(54) DATA OUTPUT CIRCUIT

(75) Inventor: Sang Kwon LEE, Gyeonggi-do (KR)

(73) Assignee: HYNIX SEMICONDUCTOR INC., Gyeonggi-do (KR)

(21) Appl. No.: 12/825,799

(22) Filed: Jun. 29, 2010

(30) Foreign Application Priority Data
Oct. 30, 2009 (KR) 10-2009-0104366

(51) Int. Cl. H03K 3/00

(52) U.S. Cl. 327/108

(57) ABSTRACT

The data output circuit includes a first decoder, a second decoder, a first selective output circuit, a second selective output circuit, and an output driver. The first decoder is configured to generate a pull-up selection signal by decoding a pull-up code. The second decoder is configured to generate a pull-down selection signal by decoding a pull-down code. The first selective output circuit is configured to select and output a voltage level of a pull-up level signal in response to the pull-up selection signal. The second selective output circuit is configured to select and output a voltage level of a pull-down level signal in response to the pull-down selection signal. The output driver is configured to drive output data in response to receiving a pre-pull-up signal and a pre-pull-down signal.

### CROSS-REFERENCE TO RELATED APPLICATIONS

The present application claims priority under 35 U.S.C. 119(a) to Korean Application No. 10-2009-104366, filed on Oct. 30, 2009, in the Korean Intellectual Property Office, which is incorporated by reference in its entirety as set forth in full.

### BACKGROUND

The present invention relates to a data output circuit.

Mobile-specific double data rate dynamic random access memories (mobile DDR DRAMs) or mobile DDR2 DRAMs are generally operating without terminations in view of input interface, for those memories are required to be operable in low power by the portable environment. Instead of that, for the purpose of assuring stable signal integrity against impedance of signal lines along with package substrates, it is necessary to substantially achieve slew rates suitable for impedance circumstances of semiconductor memories.

FIG. 1 shows a general data output circuit.

As shown in FIG. 1, the data output circuit is formed of an inverter IV10, a resistor R10, a capacitor C10, an inverter IV11, a resistor R11, a capacitor C11, a PMOS transistor P10 and an NMOS transistor N10. The inverter IV10 inversely buffers a pre-pull-up signal PU0 that is activated to a high level state when data is conditioned on a high level state. The inverter IV11 inversely buffers a pre-pull-down signal PDB0 that is activated to a low level state when data is conditioned on a low level state. The PMOS transistor P10 raises a voltage level of the first output data DOUT1 in response to the first pull-up signal PUB1. The NMOS transistor N10 decreases a voltage level of the first output data DOUT1 in response to the first pull-down signal PD1.

With this type of data output circuit configuration, it is possible to provide slew rates suitable for a given impedance circumstance of a semiconductor memory by adjusting the RC delay time constants which are determined by the resistors R10 and R11 and the capacitors C10 and C11. However, using these types of passive elements, i.e., resistors and capacitors, results in unacceptable increases in the layout of this type of data output circuit configuration.

### SUMMARY

Accordingly, the present invention is directed to a data output circuit capable of easily adjusting a slew rate without passive elements.

The data output circuit may include: a first decoder configured to generate a pull-up selection signal by decoding a pull-up code; a second decoder configured to generate a pull-down selection signal by decoding a pull-down code; a first selective output circuit configured to select and output a voltage level of a pull-up level signal in response to the pull-up selection signal; a second selective output circuit configured to select and output a voltage level of a pull-down level signal in response to the pull-down selection signal; and an output driver configured to drive output data in response to receiving a pre-pull-up signal and a pre-pull-down signal. The drivability of the output data is determined by voltage levels of the pull-up level signal and the pull-down level signal.

The data output circuit may include: a first transmission element configured to have turn-on resistance determined by voltage levels of a pull-up level signal and a pull-down level signal and configured to transfer a buffered signal of a pre-pull-up signal as a pull-up signal; a second transmission element configured to have turn-on resistance determined by voltage levels of the pull-up level signal and the pull-down level signal and configured to transfer a buffered signal of a pre-pull-down signal as a pull-down signal; and a driving circuit configured to drive output data in response to the pull-up signal and the pull-down signal.

A further understanding of the nature and advantages of the present invention herein may be realized by reference to the remaining portions of the specification and the attached drawings.

### BRIEF DESCRIPTION OF THE DRAWINGS

The above and other aspects, features and other advantages will be more clearly understood from the following detailed description taken in conjunction with the accompanying drawings, in which:

FIG. 1 shows a general data output circuit;

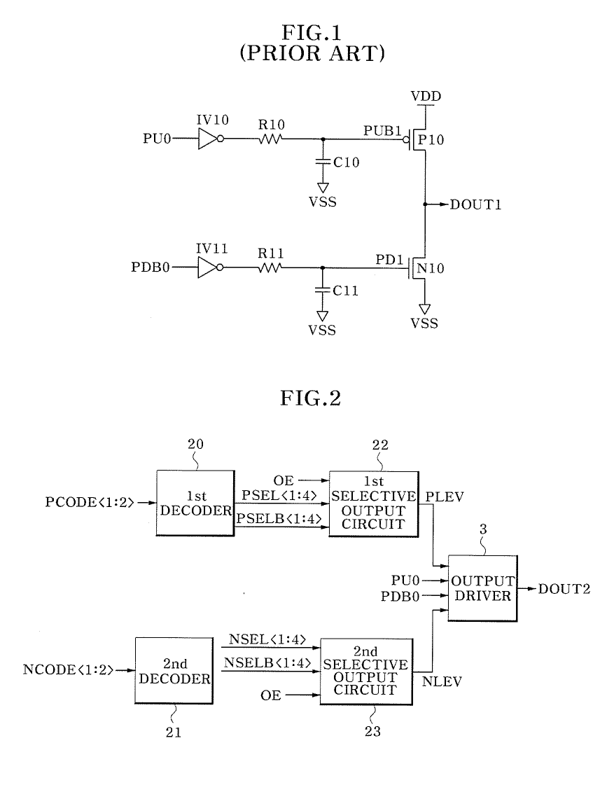

FIG. 2 is a block diagram illustrating an organization of a data output circuit according to an embodiment of the present invention;

FIGS. 3 and 4 are circuit diagrams illustrating the first and second decoders included in the data output circuit shown in FIG. 2;

FIGS. 5 and 6 circuit diagrams illustrating the first and second selective output circuit included in the data output circuit shown in FIG. 2; and

FIG. 7 is a circuit diagram illustrating the output driver included in the data output circuit shown in FIG. 2.

### DESCRIPTION OF EMBODIMENTS

Hereinafter, various embodiments will now be described more fully with reference to the accompanying drawings in which some embodiments are shown. However, specific structural and functional details disclosed herein are merely representative for purposes of describing embodiments of the present invention. Like numbers refer to like elements throughout the description of the drawings.

The terminology used herein is for the purpose of describing particular embodiments only and is not intended to be limiting of embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Further, it will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the invention. As used herein, the term “and/or” includes any and all combinations of one or more of the associated listed items. Also will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

In order to more specifically describe embodiments, various aspects will be hereinafter described in detail with reference to the attached drawings.

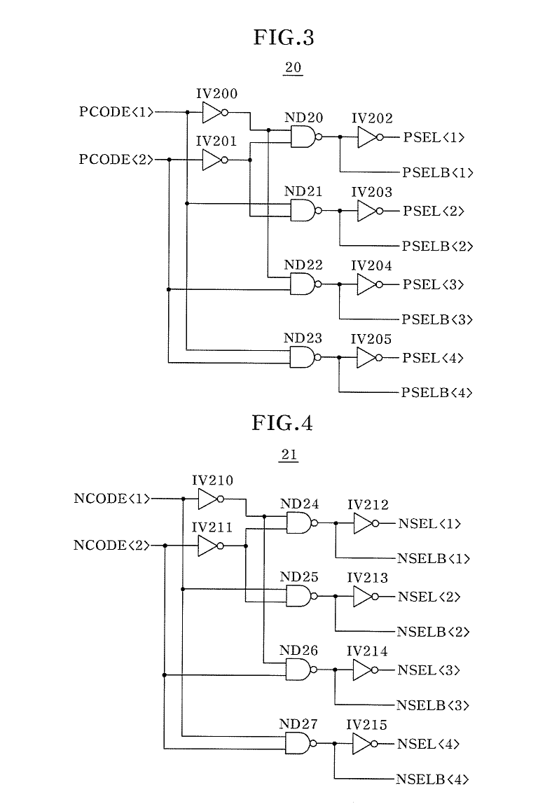

FIG. 2 is a block diagram illustrating an organization of a data output circuit according to an embodiment of the present invention.

Referring to FIG. 2, the data output circuit according to this embodiment may be comprised of a first decoder 20, a second decoder 21, a first selective output circuit 22, a second selective output circuit 23 and an output driver 3.

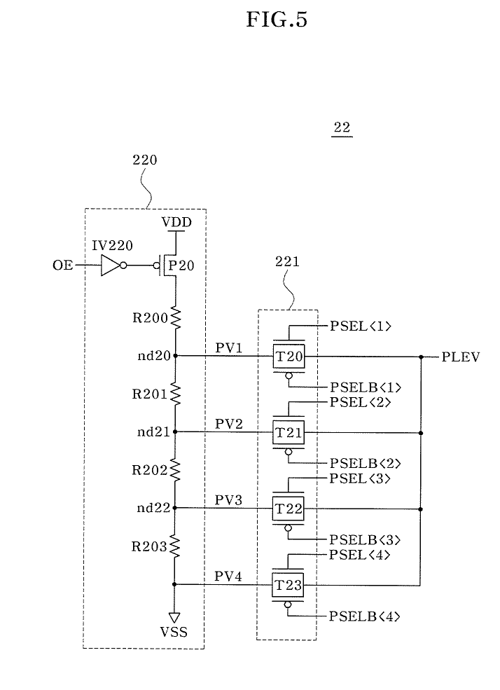

Referring to FIG. 3, the first decoder 20 is exemplarily composed of inverters IV200˜IV205 and NAND gates ND20˜ND23, and generates first through fourth pull-up selection signals PSEL<1:4> and first through fourth inverted pull-up selection signals PSELB<1:4> by decoding first and second pull-up codes PCODE<1:2>. From Table 1, it can be seen that logical states of the first through fourth pull-up selection signals PSEL<1:4> generated from the first decoder 20 are established by combinations of the first and second pull-up codes PCODE<1:2>.

TABLE 1

| PCODE | PCODE | PSEL | PSEL | PSEL | PSEL |
|---|---|---|---|---|---|
| <2> | <1> | <1> | <2> | <3> | <4> |
| L | L | H | L | L | L |
| L | H | L | H | L | L |
| H | L | L | L | H | L |
| H | H | L | L | L | H |

Referring to FIG. 4, the second decoder 21 is exemplarily composed of inverters IV210˜IV215 and NAND gates ND24˜ND27, and generates first through fourth pull-down selection signals NSEL<1:4> and first through fourth inverted pull-down selection signals NSELB<1:4> by decoding first and second pull-down codes NCODE<1:2>. From Table 2, it can be seen that logical states of the first through fourth pull-down selection signals NSEL<1:4> generated from the second decoder 21 are established by combinations of the first and second pull-down codes NCODE<1:2>.

TABLE 2

| NCODE | NCODE | NSEL | NSEL | NSEL | NSEL |
|---|---|---|---|---|---|
| <2> | <1> | <1> | <2> | <3> | <4> |
| L | L | H | L | L | L |
| L | H | L | H | L | L |
| H | L | L | L | H | L |
| H | H | L | L | L | H |

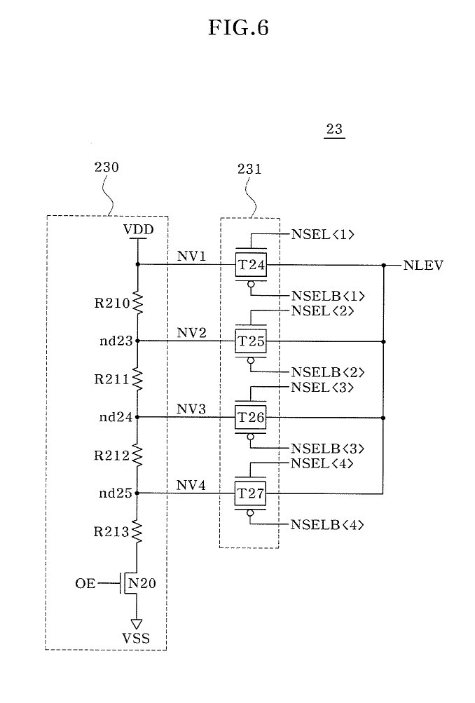

Referring to FIG. 5, the first selective output circuit 22 may be organized as a first voltage divider 220 and a first transmission circuit 221. The first voltage divider 220 is exemplarily composed of an inverter IV220, a PMOS transistor P20 and a plurality of resistive elements R200˜R203. The inverter IV220 inversely buffers an output enable signal OE. The PMOS transistor P20 operates as a switch that is turned on in response to an output signal of the inverter IV220 so as to supply an external voltage VDD. The resistive elements (or resistors) R200˜R203 are serially coupled between the PMOS transistor P20 and the ground voltage VSS. The first transmission circuit 221 is exemplarily composed of transmission gates T20˜T23. The transmission gate T20 transfers a first divided pull-up voltage PV1 as a pull-up level signal PLEV from a node nd20 in response to the first pull-up selection signal PSEL<1> and the first inverted pull-up selection signal PSELB<1>. The transmission gate T21 transfers a second divided pull-up voltage PV2 as the pull-up level signal PLEV from a node nd21 in response to the second pull-up selection signal PSEL<2> and the second inverted pull-up selection signal PSELB<2>. The transmission gate T22 transfers a third divided pull-up voltage PV3 as the pull-up level signal PLEV from a node nd22 in response to the third pull-up selection signal PSEL<3> and the third inverted pull-up selection signal PSELB<3>. The transmission gate T23 transfers a fourth divided pull-up voltage PV4 as the pull-up level signal PLEV in response to the fourth pull-up selection signal PSEL<4> and the fourth inverted pull-up selection signal PSELB<4>. The output enable signal OE is activated in a high level state during a write operation mode.

Referring to FIG. 6, the second selective output circuit 23 may be organized as a second voltage divider 230 and a second transmission circuit 231. The second voltage divider 230 is exemplarily composed of an NMOS transistor N20 and a plurality of resistive elements (or resistors) R210˜R213. The NMOS transistor N20 operates as a switch turned on in response to the output enable signal OE so as to supply the ground voltage VSS. The resistive elements R210˜R213 are serially coupled between the external voltage VDD and the NMOS transistor N20. The second transmission circuit 231 is exemplarily composed of transmission gates T24˜T27. The transmission gate T24 transfers a first divided pull-down voltage NV1, which is leveled on the external voltage VDD, as a pull-down level signal NLEV in response to the first pull-down selection signal NSEL<1> and the first inverted pull-down selection signal NSELB>1>. The transmission gate T25 transfers a second divided pull-down voltage NV2 as the pull-down level signal NLEV from a node nd23 in response to the second pull-down selection signal NSEL<2> and the second inverted pull-down selection signal NSELB<2>. The transmission gate T26 transfers a third divided pull-down voltage NV3 as the pull-down level signal NLEV from a node nd24 in response to the third pull-down selection signal NSEL<3> and the third inverted pull-down selection signal NSELB<3>. The transmission gate T27 transfers a fourth divided pull-down voltage NV4 as the pull-down level signal NLEV from a node nd25 in response to the fourth pull-down selection signal NSEL<4> and the fourth inverted pull-down selection signal NSELB<4>.

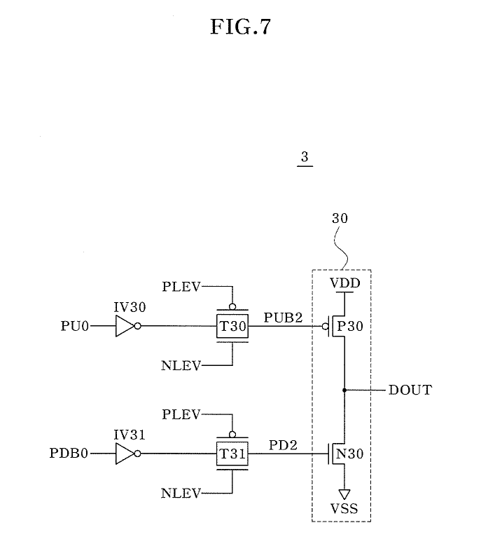

Referring to FIG. 7, the output driver 3 may be comprised of an inverter IV30, a transmission gate T30, an inverter IV31, a transmission gate T31, a PMOS transistor P30 and an NMOS transistor N30. The inverter IV30 inversely buffers a pre-pull-up signal PU0. The transmission gate T30 transfers an output signal of the inverter IV30 as a second pull-up signal PUB2 in response to the pull-up level signal PLEV and the pull-down level signal NLEV. The inverter IV31 inversely buffers a pre-pull-down signal PDB0. The transmission gate T31 transfers an output signal of the inverter IV31 as a second pull-down signal PD2 in response to the pull-up level signal PLEV and the pull-down level signal NLEV. The output driver 3 may be configured to have a driving circuit 30 that receives the second pull-up signal PUB2 and the second pull-down signal PD2 to output drive the output data DOUT. The PMOS transistor P30 raises a voltage level of the output data DOUT to the external voltage VDD in response to the second pull-up signal PUB2. The NMOS transistor N30 decreases a voltage level of the output data DOUT to the ground voltage VSS in response to the second pull-down signal PD2. The pre-pull-up signal PU0 is activated on a high level state when data is input in a high level state. The pre-pull-down signal PDB0 is activated on a low level state when data is input in a high level state. The transmission gates T30 and T31 are preferably configured to have smaller turn-on resistance as a voltage level of the pull-up level signal PLEV is lower and as a voltage level of the pull-down level signal NLEV is higher.

An operation of the data output circuit with this configuration is as follows.

In the beginning, the first decoder 20 generates the first through fourth pull-up selection signals PSEL<1:4> and the first through fourth inverted pull-up selection signals PSELB<1:4> by decoding the first and second pull-up codes PCODE<1:2>. The second decoder 21 generates the first through fourth pull-down selection signals NSEL<1:4> and the first through fourth inverted pull-down selection signals NSELB<1:4> by decoding the first and second pull-down codes NCODE<1:2>.

Next, the first selective output circuit 22 outputs one of the first through fourth divided pull-up voltages PV1˜PV4 as the pull-up level signal PLEV in response to the first through fourth pull-up selection signals PSEL<1:4> and the first through fourth inverted pull-up selection signals PSELB<1:4>. The second selective output circuit 23 outputs one of the first through fourth divided pull-down voltages NV1˜NV4 as the pull-down level signal NLEV in response to the first through fourth pull-down selection signals NSEL<1:4> and the first through fourth inverted pull-down selection signals NSELB<1:4>. Here, the pull-up level signal PLEV is generated at the minimum voltage level when the fourth pull-up selection signal PSEL<4> is activated in a high level state and the fourth inverted pull-up selection signal PSELB<4> is activated in a low level. Further, the pull-down level signal NLEV is generated at the minimum voltage level when the first pull-down selection signal NSEL<1> is activated in a high level state and the first inverted pull-down selection signal NSELB<1> is activated in a low level.

Then, the output driver 3 determines voltage levels of the second pull-up signal PUB2 and the second pull-down signal PD2 depending on voltage levels of the pull-up level signal PLEV and the pull-down level signal NLEV. According to the determined voltage levels of the second pull-up signal PUB2 and the second pull-down signal PD2, the output data DOUT is driven. During this, when data is input in a high level state, the transmission gate T30 transfers a low level signal as the second pull-up signal PUB2. As a voltage level of the pull-up level signal PLEV is lower and a voltage level of the pull-down level signal NLEV is higher, the turn-on resistance of the transmission gate T30 becomes smaller to make a voltage level of the second pull-up signal PUB2 be closer to the ground voltage VSS. On the other hand, when data is input in a low level state, the transmission gate T31 transfers a high level signal as the second pull-down signal PD2. As a voltage level of the pull-up level signal PLEV is lower and a voltage level of the pull-down level signal NLEV is higher, the turn-on resistance of the transmission gate T31 becomes smaller to make a voltage level of the second pull-down signal PD2 be closer to the external voltage VDD. In the meantime, as a voltage level of the pull-up level signal PLEV is higher and a voltage level of the pull-down level signal NLEV is lower, the output driver 3 operates so much to have smaller drivability for driving the output data. This smaller drivability is effective in reducing a slew rate.

In summary, the data output circuit according to this embodiment is useful to precisely control a slew rate by determining voltage levels of the pull-up level signal PLEV and the pull-down level signal NLEV from the logical combinations of the first and second pull-up codes PCODE<1:2> and the first and second pull-down codes NCODE<1:2> and by adjusting the turn-on resistance of the transmission gates T30 and T31 from the voltage levels of the pull-up level signal PLEV and the pull-down level signal NLEV.

The foregoing is illustrative of embodiments and is not to be construed as limiting thereof. Although a few embodiments have been described, those skilled in the art will readily appreciate that many modifications are possible in embodiments without materially departing from the novel teachings and advantages. Accordingly, all such modifications are intended to be included within the scope of this invention as defined in the claims.

What is claimed is:

1. A data output circuit comprising:
a first decoder configured to generate a pull-up selection signal by decoding a pull-up code;
a second decoder configured to generate a pull-down selection signal by decoding a pull-down code;
a first selective output circuit configured to select and output a voltage level of a pull-up level signal in response to the pull-up selection signal;
a second selective output circuit configured to select and output a voltage level of a pull-down level signal in response to the pull-down selection signal; and
an output driver configured to drive output data in response to receiving a pre-pull-up signal and a pre-pull-down signal, wherein drivability of the output data is determined by voltage levels of the pull-up level signal and the pull-down level signal.

2. The data output circuit according to claim 1, wherein the first selective output circuit comprises:
a voltage divider configured to generate first and second divided pull-up voltages by dividing an external voltage in response to an output enable signal; and
a transmission circuit configured to transfer the first divided pull-up voltage or the second divided pull-up voltage as the pull-up level signal in response to the first and second pull-up selection signals.

3. The data output circuit according to claim 2, wherein the voltage divider comprises:
a switching element turned on in response to the output enable signal and configured to supply the external voltage;
a first resistive element coupled between the switching element and a first node from which the first divided pull-up voltage is output; and
a second resistive element coupled between the first node and a second node from which the second divided pull-up voltage is output.

4. The data output circuit according to claim 3, wherein the transmission circuit comprises:
a first transmission element configured to transfer the first divided pull-up voltage as the pull-up level signal in response to the first pull-up selection signal; and
a second transmission element configured to transfer the second divided pull-up voltage as the pull-up level signal in response to the second pull-up selection signal.

5. The data output circuit according to claim 1, wherein the second selective output circuit comprises:
a voltage divider configured to generate first and second divided pull-down voltages by dividing an external voltage in response to an output enable signal; and
a transmission circuit configured to transfer the first divided pull-down voltage or the second divided pull-down voltage as the pull-down level signal in response to the first and second pull-down selection signals.

6. The data output circuit according to claim 5, wherein the voltage divider comprises:
a switching element turned on in response to the output enable signal and configured to supply a ground voltage;
a first resistive element coupled between the switching element and a first node from which the first divided pull-down voltage is output; and
a second resistive element coupled between the first node and a second node from which the second divided pull-down voltage is output.

7. The data output circuit according to claim 6, wherein the transmission circuit comprises:
a first transmission element configured to transfer the first divided pull-down voltage as the pull-down level signal in response to the first pull-down selection signal; and
a second transmission element configured to transfer the second divided pull-down voltage as the pull-down level signal in response to the second pull-down selection signal.

8. The data output circuit according to claim 1, wherein the output driver comprises:
a first buffer configured to buffer the pre-pull-up signal;
a first transmission element configured to transfer an output signal of the first buffer as a pull-up signal in response to the pull-up level signal and the pull-down level signal;
a second buffer configured to buffer the pre-pull-down signal;
a second transmission element configured to transfer an output signal of the second buffer as a pull-down signal in response to the pull-up level signal and the pull-down level signal; and
a driving circuit configured to drive the output data in response to the pull-up level signal and the pull-down level signal.

9. A data output circuit comprising:
a first transmission element configured to have turn-on resistance determined by voltage levels of a pull-up level signal and a pull-down level signal and configured to transfer a buffered signal of a pre-pull-up signal as a pull-up signal;
a second transmission element configured to have turn-on resistance determined by voltage levels of the pull-up level signal and the pull-down level signal and configured to transfer a buffered signal of a pre-pull-down signal as a pull-down signal; and
a driving circuit configured to drive output data in response to the pull-up signal and the pull-down signal.

10. The data output circuit according to claim 9, wherein the pull-up level signal is selected as one from a plurality of voltages that are set by dividing an external voltage in response to a pull-up code.

11. The data output circuit according to claim 9, wherein the pull-down level signal is selected as one from a plurality of voltages that are set by dividing an external voltage in response to a pull-down code.
